(19) United States
(12) Patent Application Publication
(10) Pub. No.: US 2026/0191023 A1
(43) Pub. Date: Jul. 2, 2026

(54) AUTOMATIC PUNCH LEVEL ADJUSTMENT IN A PRESS SYSTEM

(71) Applicant: ASMPT Singapore Pte. Ltd., Singapore (CN)

(72) Inventors: Wang Lung TSE, Hong Kong SAR (CN); Cheung Yuen SO, Hong Kong SAR (CN); Hong Yeung LI, Hong Kong SAR (CN); Chi Wah CHENG, Hong Kong SAR (CN)

(21) Appl. No.: 19/003,778

(22) Filed: Dec. 27, 2024

(51) Int. Cl. H01L 21/48

(52) U.S. Cl. CPC H10W 70/048

(57) ABSTRACT

A press system for punching multiple leads of an electronic device includes a body casting onto which a first die set is fixedly attached, and a second die set which is drivable to move relative to the first die set between a standby level where the first and second die sets are at a preset separation distance and a punch level where a punching force is applied onto the leads of the electronic device by the first and/or second die sets. A fine-tuning motor operatively coupled to the body casting is operative to adjust a position of the body casting to vary the preset separation distance between the first and second die sets, whereby to automatically vary the punch level for punching a subsequent electronic device using the first and second die sets.

### FIELD OF THE INVENTION

The invention relates to a mechanical press for electronic devices, and in particular to a mechanical press having automatic adjustment features for improving output quality of the electronic devices being processed.

### BACKGROUND AND PRIOR ART

Mechanical presses are conventionally used in the semiconductor assembly and packaging industry to cut, bend, form or separate electronic devices or components by punching. Press manufacturers of conventional mechanical presses generally focus on running the mechanical press with a regular and constant reciprocating motion.

To improve flexibility, some manufacturers integrate an additional vision system to monitor the output for quality problems, and to stop the operation of the mechanical press if any deficiencies are discovered. For example, if a forming angle or a lead-to-lead pitch of an electronic device being output is outside specification limits, the tooling parts are adjusted manually after the mechanical press is stopped, to avoid such defect from appearing in subsequent electronic devices being processed. It has not been a consideration of manufacturers to fine-tune the amount of press drive-in to adjust or improve the quality of the output, over and above just focusing on remedying the situation when obvious defects are found on the electronic devices being packaged.

A shortcoming of the above approach is that production is only stopped if defects are discovered during preventive maintenance or visual inspection. Furthermore, problematic tooling parts have to be adjusted or changed manually to maintain output quality, such as those caused by wear and tear.

It would be beneficial to design a mechanical press which avoids the aforesaid shortcomings of the prior art.

### SUMMARY OF THE INVENTION

It is thus an object of the invention to seek to provide a mechanical press that can automatically adjust a press drive-in to improve quality of the output without having to stop the mechanical press during processing operations.

According to a first aspect of the invention, there is provided a press system for punching multiple leads of an electronic device, the press system comprising: a body casting onto which a first die set is fixedly attached; a second die set which is drivable to move relative to the first die set between a standby level where the first and second die sets are at a preset separation distance and a punch level where a punching force is applied onto the leads of the electronic device by the first and/or second die sets; and a fine-tuning motor operatively coupled to the body casting, the fine-tuning motor being operative to adjust a position of the body casting to vary the preset separation distance between the first and second die sets, whereby to automatically vary the punch level for punching a subsequent electronic device using the first and second die sets.

According to a second aspect of the invention, there is provided a method for manufacturing electronic devices by punching multiple leads of the electronic devices in a press system, comprising the steps of: fixedly attaching a first die set onto a body casting; driving a second die set to move relative to the first die set between a standby level where the first and second die sets are at a preset separation distance and a punch level where a punching force is applied onto leads of an electronic device by the first and/or second die sets to punch the leads; and adjusting a position of the body casting with a fine-tuning motor that is operatively coupled to the body casting to vary the preset separation distance between the first and second die sets, whereby to automatically vary the punch level for punching a subsequent electronic device using the first and second die sets; and punching the subsequent electronic device at the varied punch level.

It would be convenient hereinafter to describe the invention in greater detail by reference to the accompanying drawings which illustrate specific preferred embodiments of the invention. The particularity of the drawings and the related description is not to be understood as superseding the generality of the broad identification of the invention as defined by the claims.

### BRIEF DESCRIPTION OF THE DRAWINGS

A specific example of an alignment system and method in accordance with the invention will now be described with reference to the accompanying drawings, in which:

FIG. 1 is a side view of an electronic device wherein its leads are being formed by a mechanical press;

FIG. 2 is an isometric view of a press system according to the preferred embodiment of the invention illustrating a feedback system for automatically adjusting a punch level of a mechanical press;

FIG. 3 is an exemplary flow-chart illustrating how the press system may automatically adjust the punch level of the mechanical press;

FIG. 4 is a side view of a mechanical press showing how the automatic punch level adjustment may be implemented according to a first embodiment of the mechanical press; and

FIG. 5 is a side view of a mechanical press showing how the automatic punch level adjustment may be implemented according to a second embodiment of the mechanical press.

### DETAILED DESCRIPTION OF THE PREFERRED EMBODIMENTS OF THE INVENTION

FIG. 1 is a side view of an electronic device 100 wherein its leads 102 are being formed by a mechanical press by punching the leads 102 during the manufacture of the electronic device 100. The electronic device 100, typically comprised in a lead frame, is positioned between an upper die set 10A and a lower die set 10B of the mechanical press. Clamping parts 12 of the upper and lower die sets 10A, 10B clamp onto a portion of the leads 102 on opposite sides of the electronic device 100. Forming punches 14 adjacent to the clamping parts 12 push down against and punch the ends of the leads 102 relative to the clamping parts 12 up to a punch level 18 so that the leads 102 are bent and are formed into a Z-shape.

A depth to which the forming punch 14 pushes against and punches the leads 102 determines a lead angle 16 of the leads 102. This lead angle 16 should be within a certain defined specification, which is generally determined by the punching depth or punch level 18. Due to wear and tear of the mechanical press from repeated use, such as from wearing of the surface of the forming punch 14, the lead angle 16 may start to change. Therefore, it would be beneficial to be able to automatically control the punching depth or level to ensure that the lead angle 16 is maintained within required specifications without the need for manual intervention.

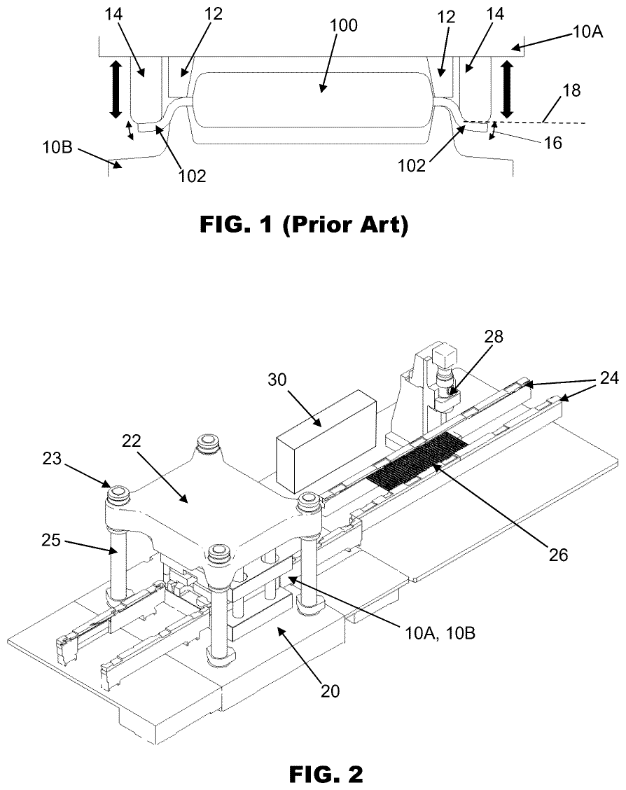

FIG. 2 is an isometric view of a press system according to the preferred embodiment of the invention illustrating a feedback system for automatically adjusting a punch level 18 of a mechanical press 20. The press system generally includes a mechanical press 20, an image sensor such as a CCD camera 28, a fine-tuning motor controller 30 and conveyor rails 24. The conveyor rails 24 are configured for bidirectionally conveying a lead frame 26 (and electronic devices 100 thereon) from a position of the mechanical press 20 where the upper and lower die sets 10A, 10B are situated to a location of the CCD camera 28, and then to an offloading position (not shown) where the lead frame 26 may be removed after processing. Each lead frame 26 typically contains multiple electronic devices 100 arranged in a matrix format, and their leads 102 need to be formed at the mechanical press 20 during processing.

The mechanical press 20 includes a body casting 22 located at a top portion of the mechanical press 20, and the body casting 22 is supported by and mounted onto multiple columns 25 using screws 23. The body casting 22 is slidably movable on the multiple columns 25 for adjusting a position of the body casting 22. Both the body casting 22 and the lower die set 10B are drivable to slidably move along the multiple columns 25.

In this embodiment, a first die set in the form of the upper die set 10A is fixedly attached to the body casting 22 and held relatively stationary during a punching operation. On the other hand, a second die set in the form of the lower die set 10B is generally drivable to move up and down relative to the upper die set 10A between a standby level which represents a maximum preset separation distance between the upper and lower die sets 10A, 10B and a punch level 18 where a punching force is applied onto the leads 102 of the electronic device 100 by the upper and/or lower die sets 10A, 10B. During a punching operation, the lower die set 10B is configured to move from the standby level to bring the electronic devices 100 of the lead frame 26 to the punch level 18 to contact the forming punch 14 in order to bend the leads 102 by punching, as described in relation to FIG. 1.

After the leads 102 have been bent and formed at the mechanical press 20, the conveyor rails 24 move the lead frame 26 from the mechanical press 20 to a position underneath the CCD camera 28, where the leads 102 are to be inspected by the CCD camera 28. An image of the leads 102 that have been punched is captured by the CCD camera 28 and is transmitted to a fine-tuning motor controller 30 which is configured to determine from a result of punching an electronic device 100 whether the punch level 18 should be varied. In this instance, the fine-tuning motor controller 30 inspects and optically determines whether the leads 102 are formed with a lead angle 106 that is within a predetermined specification. If it is determined that the lead angle 106 need to be adjusted, the fine-tuning motor controller 30 may then provide signals to adjust a position of the body casting 22 to a necessary extent, so as to maintain the lead angle 106 within the required predetermined specification.

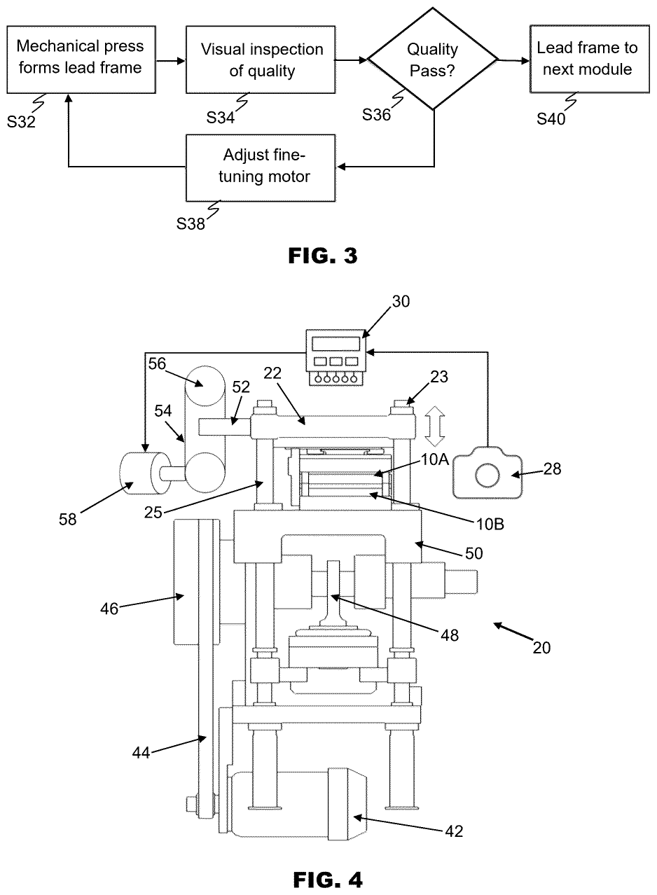

FIG. 3 is an exemplary flow-chart illustrating how the press system may automatically adjust the punch level 18 of the mechanical press 20. After a lead frame 26 has been formed by the mechanical press 20 and is conveyed away from the mechanical press 20 (S32), visual inspection is conducted by the CCD camera 28 to check the quality of the leads 102 of the electronic devices 100 (S34). Next, the fine-tuning motor controller 30 determines whether the quality of the lead frame 100 is acceptable (S36).

If the quality of the lead frame 100 is not acceptable, the fine-tuning motor controller 30 will automatically adjust the mechanical press 20 to ensure that a punching depth or level of the upper die set 10A is adequate for processing the next lead frame 26 (S38). If the quality of the lead frame 100 is acceptable, no adjustment is required and the lead frame 100 is conveyed to the next module (S40), such as an offloading module.

FIG. 4 is a side view of a mechanical press 20 showing how the automatic punch level adjustment may be implemented according to a first embodiment of the mechanical press 20. The mechanical press 20 has a mechanical press motor 42 which drives a press belt 44 connected to a press pulley in order to turn the press pulley 46. Turning of the press pulley 46 in turn drives a crank 48 which serves to raise or to lower a lower platen 50 on which the lower die set 10B is installed. When a lead frame 26 is placed between the upper die set 10A and the lower die set 10B, the lower platen 50 raises the lower die set 10A towards the upper die set 10B while the upper die set 10B remains relatively stationary. The lower die set 10B will continue to be raised until the forming punches 14 on the upper die set 10A completely bend the leads 102 on the electronic device 100.

Additionally, the body casting 22 is configured to be adjustable along the columns 25 on which it is supported. To achieve this, there is an extension arm 52 which protrudes from the body casting 22. The extension arm 52 is connected to a fine-tuning belt 54 that is driven by a fine-tuning motor 58 via a pulley 56, thus operatively coupling the fine-tuning motor 58 to the body casting 22. In this way, the fine-tuning motor 58 is operative to adjust a position of the body casting 22 to vary the maximum preset separation distance between the upper and lower die sets 10A, 10B relating to the standby level of the lower die set 10B, thereby automatically varying the punch level 18 for punching a subsequent electronic device 100 using the upper and/or lower die sets 10A, 10B.

After the CCD camera 28 captures an image of a lead frame 26, the fine-tuning motor controller 30 processes the image to determine whether the leads 102 have been formed within the required dimensional specifications. If for instance, after a certain period of usage, it is determined that the punch level 18 needs to be increased, the fine-tuning motor controller 30 will send a signal to the fine-tuning motor 58 to actuate the fine-tuning motor 58 to adjust the position of the body casting 22. Where it is necessary to increase the punch level 18, the fine-tuning motor 58 will operate to rotate the belt in a clockwise direction in FIG. 4, in order to lower the extension arm 52 such that the body casting 22 and the upper die set 10A mounted on it are shifted closer to the lower die set 10B. As a result, penetration of the forming punch 14 against the leads 102 relative to the lower die set 10B would be increased, thereby increasing the punch level 18.

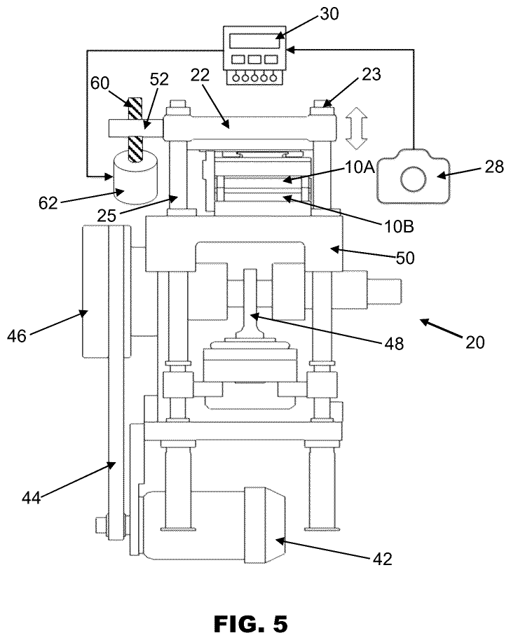

FIG. 5 is a side view of a mechanical press 20 showing how the automatic punch level adjustment may be implemented according to a second embodiment of the mechanical press 20. In this embodiment, the extension arm 52 which protrudes from the body casting 22 is connected to a ball screw 60 instead of a fine-tuning belt 54. The ball screw 60 is drivable to rotate by a fine-tuning motor 62 (such as a stepper motor) in order to raise or lower the extension arm 54. Similar to the previous embodiment, raising or lowering the extension arm 54 correspondingly raises or lowers the body casting 22 along the columns 25 on which it is supported.

In this embodiment, after the CCD camera 28 captures an image of the lead frame 26, the fine-tuning motor controller 30 processes the image to determine whether the leads 102 have been formed within the required specifications. If it is determined that the punch level 18 needs to be increased, the fine-tuning motor controller 30 will send a signal to the fine-tuning motor 62. Where it is necessary to increase the punch level 18, the fine-tuning motor 62 will rotate the ball screw 60 in such a way that the extension arm 52 connected to the ball screw 60 is lowered. Accordingly, the body casting 22 and the upper die set 10A mounted on it are shifted closer to the lower die set 10B. As a result, penetration of the forming punch 14 against the leads 102 relative to the lower die set 10B would be increased, thereby increasing the punch level 18.

Apart from the electronic devices 100 described in relation to FIG. 1, the embodiments of the inventions may also be used to punch specialized lead frames such as those described in U.S. Pat. No. 11,264,310.

Other than optical or visual inspection of the lead frames 26, it would be apparent to a person skilled in the art that data feedback may also be provided to the fine-tuning motor controller 30 by adopting alternative means, such as the fine-tuning motor controller 30 measuring a reaction force from the leads 102 of the electronic device 100 when the upper and/or lower die sets 10A, 10B clamp onto the leads 102. Another approach is for the fine-tuning motor controller 30 to measure positional feedback relating to the relative positions of the upper and lower die sets 10A, 10B at a point where the upper and/or lower die sets 10A, 10B clamp onto the leads 102 of the electronic device 100. Other measurement methods may also be adopted. Based on such data feedback, the fine-tuning motor controller 30 may provide signals for adjusting the position of the body casting 22 and therefore the punch level 18.

It should be appreciated that the press systems according to the preferred embodiments of the invention are capable of sustainably achieving automation in maintaining a quality of the processed lead frames 26 without the need for manual intervention. Therefore, the throughput can be improved and the output quality may be continuously maintained.

The invention described herein is susceptible to variations, modifications and/or additions other than those specifically described and it is to be understood that the invention includes all such variations, modifications and/or additions which fall within the spirit and scope of the above description.

1. A press system for punching multiple leads of an electronic device, the press system comprising:
a body casting onto which a first die set is fixedly attached;
a second die set which is drivable to move relative to the first die set between a standby level where the first and second die sets are at a preset separation distance and a punch level where a punching force is applied onto the leads of the electronic device by the first and/or second die sets; and
a fine-tuning motor operatively coupled to the body casting, the fine-tuning motor being operative to adjust a position of the body casting to vary the preset separation distance between the first and second die sets, whereby to automatically vary the punch level for punching a subsequent electronic device using the first and second die sets.

2. The press system as claimed in claim 1, further comprising a fine-tuning motor controller which is configured to determine from a result of punching an electronic device whether the punch level should be varied.

3. The press system as claimed in claim 2, wherein the fine-tuning motor controller is operative to provide signals to the fine-tuning motor to actuate the fine-tuning motor to adjust the position of the body casting.

4. The press system as claimed in claim 2, wherein the fine-tuning motor controller is configured to determine whether the punch level should be varied by measuring a reaction force from the leads of the electronic device when the first and/or second die sets clamp onto the leads.

5. The press system as claimed in claim 2, wherein the fine-tuning motor controller is configured to determine whether the punch level should be varied by measuring relative positions of the first and second die sets at a point when the first and/or second die sets clamp onto the leads of the electronic device.

6. The press system as claimed in claim 2, further comprising an image sensor for capturing an image of the leads that have been punched by the first and/or second die sets for inspection.

7. The press system as claimed in claim 6, further comprising conveyor rails for conveying the electronic device from a location of the first and second die sets to a location of the image sensor.

8. The press system as claimed in claim 6, wherein the fine-tuning motor controller is configured to determine whether the punch level should be varied by inspecting the image of the leads.

9. The press system as claimed in claim 1, wherein the second die set is driven by a press motor to move while the first die set is relatively stationary, so that the second die set is configured to move from the standby level to the punch level for punching the leads of the electronic device.

10. The press system as claimed in claim 1, wherein the body casting is mounted onto and supported by multiple columns along which both the body casting and the second die set are drivable to move for adjusting the position of the body casting.

11. The press system as claimed in claim 1, further comprising an extension arm protruding from the body casting, wherein the fine-tuning motor is coupled to the extension arm for adjusting the position of the body casting.

12. The press system as claimed in claim 11, wherein the extension arm is connected to a fine-tuning belt that is drivable by the fine-tuning motor via a pulley.

13. The press system as claimed in claim 11, wherein the extension arm is connected to a ball screw that is rotatable by the fine-tuning motor for adjusting the position of the body casting.

14. Method for manufacturing electronic devices by punching multiple leads of the electronic devices in a press system, comprising the steps of:
fixedly attaching a first die set onto a body casting;
driving a second die set to move relative to the first die set between a standby level where the first and second die sets are at a preset separation distance and a punch level where a punching force is applied onto leads of an electronic device by the first and/or second die sets to punch the leads; and
adjusting a position of the body casting with a fine-tuning motor that is operatively coupled to the body casting to vary the preset separation distance between the first and second die sets, whereby to automatically vary the punch level for punching a subsequent electronic device using the first and second die sets; and
punching the subsequent electronic device at the varied punch level.
